(19) United States
(12) Patent Application Publication
(10) Pub. No.: US 2023/0214556 A1
(43) Pub. Date: Jul. 6, 2023

(54) METHOD AND SYSTEM FOR GENERATING ARCHITECTURAL VECTOR MAPS

(71) Applicant: MappedIn Inc., Waterloo (CA)

(72) Inventors: Noah Bolger, Woodstock (CA); Ameneh Boroomand, Waterloo (CA); James Nathan Swidersky, Kitchener (CA)

(21) Appl. No.: 17/983,941

(22) Filed: Nov. 9, 2022

Related U.S. Application Data
(60) Provisional application No. 63/285,316, filed on Dec. 2, 2021.

(51) Int. Cl. G06F 30/27; G06F 30/13

(52) U.S. Cl. CPC G06F 30/27; G06F 30/13

(57) ABSTRACT

A method and associated system for generating vectorized architectural plans. The method includes inputting an architectural plan into a trained machine learning model, receiving a translated architectural plan as an output from the trained machine learning model, and post processing the translated architectural plan to generate a vectorized architectural plan.

### TECHNICAL FIELD

The following relates generally to architectural plan generating systems and methods, and more particularly to systems and methods for generating vectorized architectural plans by inputting architectural plan images into a trained neural network.

### INTRODUCTION

Architectural drawings or floor plans may be provided in a plurality of formats. Frequently, architectural drawings or floor plans are provided in simple image format (e.g., bitmap, .jpeg), generated from a computer-aided-drafting (CAD) system, image editing program, such as Adobe Photoshop™, or scanned from a hardcopy document. Such simple format images may be easily read by trained individuals; however, the variety of formats and notation styles may result in difficulties for untrained individuals to read.

Similarly, simple format images are not easily read and parsed by machines, as the format and styles of such images may vary widely. Simple format images may be most easily parsed when subcomponents of architectural plans (e.g. walls, windows, doorways, etc.) are easily differentiated and delineated from one another.

It may be advantageous to convert simple format architectural plans to more machine readable formats, as this may enable certain functions, such as the conversion of the plan to a digital map for modelling purposes.

Simple formats may be converted manually into machine readable formats. An operator may trace vector shapes around major components of an architectural plan. Such manual methods are time consuming and require highly trained human operators.

In other examples, a variety of computer vision and image processing methods may need to be employed to convert simple format architectural plans into machine readable data. However, such methods may be error prone, and may be unable to differentiate between architectural features, administrative features, markup and other extraneous information.

Accordingly, there is a need for an improved system and method for generating vectorized architectural plans from inputted simple format architectural plans that overcome the disadvantages of existing systems and methods.

### SUMMARY

According to an embodiment, described herein is a method of generating translated architectural plans. In at least one embodiment, the method comprise: inputting an architectural plan into a trained machine learning model and receiving a translated architectural plan as an output from the trained machine learning model.

According to some embodiments, the trained machine learning model comprises a generative adversarial network.

According to some embodiments, the trained machine learning model is trained by providing a paired training set of architectural plan images.

According to some embodiments, the paired training set comprises corresponding architectural plan and translated architectural plan pairs.

According to some embodiments, the translated architectural plan comprises at least two classes of architectural features, and the method further comprises: splitting the translated architectural plan to generate translated layers and post processing the translated layers to produce processed translated layers.

According to some embodiments, post processing comprises contourization, generating a vectorized architectural plan.

According to some embodiments, post processing comprises room segmentation.

According to some embodiments, post processing comprises simplification.

According to some embodiments, translated layers comprise at least one of walls, windows or doors.

According to some embodiments, the method further comprises manually correcting the translated layers.

According to an embodiment, described herein is a computer system for generating translated architectural plans, the system comprising: at least one processor and a memory having stored thereon instructions that, upon execution, cause the system to perform functions comprising: inputting an architectural plan into a trained machine learning model and receiving a translated architectural plan as an output from the trained machine learning model.

According to some embodiments, the trained machine learning model comprises a generative adversarial network.

According to some embodiments, the trained machine learning model is trained by providing a paired training set of architectural plan images.

According to some embodiments, the paired training set comprises corresponding architectural plan and translated architectural plan pairs.

According to some embodiments, the translated architectural plan comprises at least two classes of architectural features, the system further comprising: splitting the translated architectural plan to generate translated layers and post processing the translated plan to produce processed translated layers.

According to some embodiments, post processing comprises contourization, generating a vectorized architectural plan.

According to some embodiments, post processing comprises room segmentation.

According to some embodiments, post processing comprises simplification.

According to some embodiments, translated layers comprise at least one of walls, windows or doors.

According to some embodiments, the system further comprises manually correcting the translated layers.

According to some embodiments, the method descried herein further comprises: performing contourization on the translated architectural plan, generating a vectorized architectural plan.

According to some embodiments, the method further comprises splitting the vectorized architectural plan into vectorized layers.

According to some embodiments, the vectorized layers comprise at least one of walls, windows or doors.

Other aspects and features will become apparent to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIG. 1 is a flow chart, describing a method of generating translated architectural plans, according to an embodiment;

FIG. 2 is an example of a simple format architectural plan, for use with the method of FIG. 1;

FIG. 3 is an example of a translated architectural plan, that may comprise the final output of the method of FIG. 1, in an example wherein the plan of FIG. 2 is the input;

FIG. 4 is a flow chart, describing an alternative method of generating translated architectural plans, according to an embodiment;

FIG. 5 is an example of a training set pair of an architectural plan and a translated architectural plan, for use with the method of FIG. 4;

FIG. 6 is a block diagram, depicting a generalized generative adversarial network, according to an embodiment;

FIG. 7 is a flow chart, describing a method of generating vectorized architectural plans, according to an embodiment;

FIG. 8 is an example of a translated architectural plan split into translated layers;

FIG. 9 is a block diagram, describing a system for use with the methods of FIGS. 1, 4 and 7, according to an embodiment; and

FIG. 10 is a block diagram, describing a system for use with the methods of FIGS. 1, 4 and 7, according to another embodiment.

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

One or more systems described herein may be implemented in computer programs executing on programmable computers, each comprising at least one processor, a data storage system (including volatile and non-volatile memory and/or storage elements), at least one input device, and at least one output device. For example, and without limitation, the programmable computer may be a programmable logic unit, a mainframe computer, server, and personal computer, cloud-based program or system, laptop, personal data assistance, cellular telephone, smartphone, or tablet device.

Each program is preferably implemented in a high-level procedural or object-oriented programming and/or scripting language to communicate with a computer system. However, the programs can be implemented in assembly or machine language, if desired. In any case, the language may be a compiled or interpreted language. Each such computer program is preferably stored on a storage media or a device readable by a general or special purpose programmable computer for configuring and operating the computer when the storage media or device is read by the computer to perform the procedures described herein.

A description of an embodiment with several components in communication with each other does not imply that all such components are required. On the contrary, a variety of optional components are described to illustrate the wide variety of possible embodiments of the present invention.

Further, although process steps, method steps, algorithms or the like may be described (in the disclosure and/or in the claims) in a sequential order, such processes, methods and algorithms may be configured to work in alternate orders. In other words, any sequence or order of steps that may be described does not necessarily indicate a requirement that the steps be performed in that order. The steps of processes described herein may be performed in any order that is practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

The following relates generally to methods and systems for generating vectorized architectural plans, and more particularly to methods and systems for converting simple format architectural plans (e.g. JPEG, PNG, or rasterized CAD/vector format files) to vectorized architectural plans using machine learning based methods.

Vectorized architectural plans may advantageously be scaled infinitely without loss of quality, and may be easily parsed by machine, for conversion to digital maps, 3D models and more for various applications.

In operation of the methods and systems described herein, an operator may be provided or may generate a paired training set. For example, the operator may collect a plurality of architectural plan images. Preferably, the collection of architectural plan images are relatively similar in style and configuration to the architectural plan images that the operator wishes to vectorize using the methods described herein. For example, if the architectural plan images that the operator wishes to vectorize comprise certain line styles to denote walls and windows, where the collection of architectural plan images comprise images with similar or matching line styles, a training set may maximize the effectiveness of the method described herein.

The operator may generate corresponding translated architectural plans for each collected architectural plan, by manually placing and sizing single color components, resulting in a paired training set.

Once the operator has collected the plurality of paired training images, the paired training set may be provided to a machine learning model in raster format, to train the machine learning model. In some examples, the machine learning model may comprise a generative adversarial network which has been configured for image style transfer applications.

After the machine learning model has been trained, a simple format architectural plan may be provided as an input to the trained model. The trained model may receive the simple format architectural plan, and output a corresponding translated architectural plan.

In some examples, the methods and systems described herein may comprise further post processing steps, for example, simplification, contourization and room segmentation. After contourization, a vectorized architectural plan may be outputted. In some examples, the methods and systems described herein may comprise a manual correction or editing step.

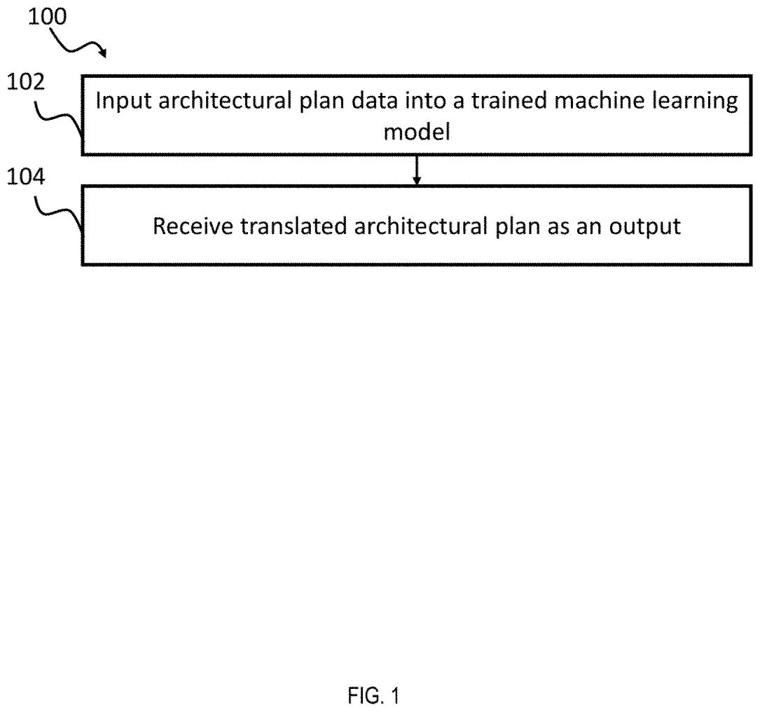

Referring first to FIG. 1, pictured therein is a method 100 of generating a translated architectural plan. Method 100 comprises steps 102, 104, 106, 108 and 110.

At step 102, architectural plan data is inputted into a trained machine learning model. In some examples, the trained machine learning model may comprise a neural network-based model. In some examples, the neural network-based model may comprise a generative adversarial network type model. The model may have been trained using a training set that enables output of translated architectural plans from the input of architectural plan data. In some examples, this training set may comprise a paired training set of architectural plans and translated architectural plans.

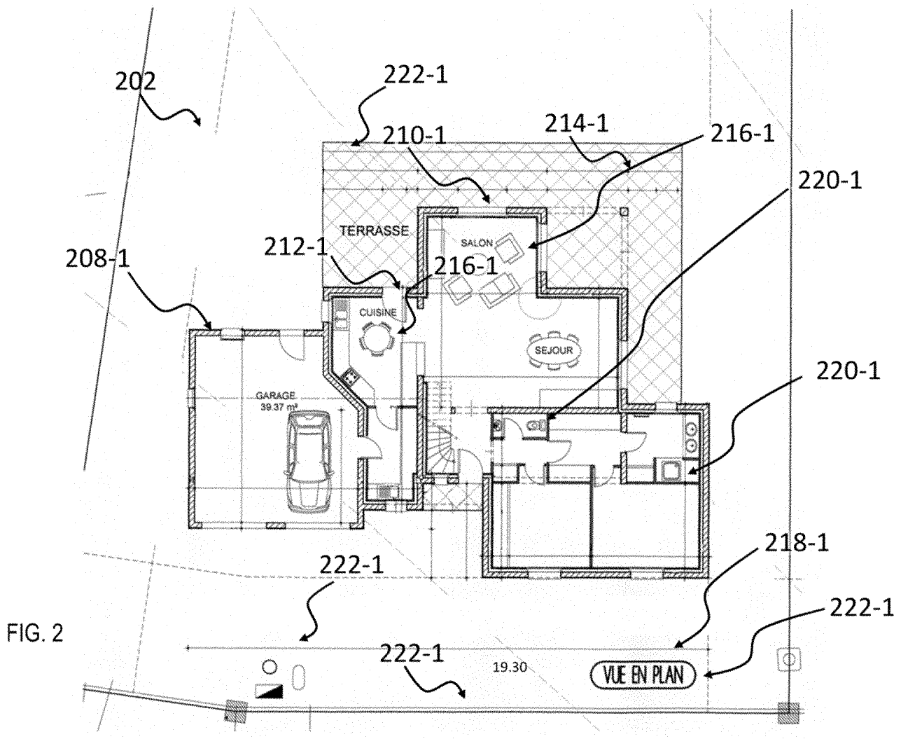

The architectural plan data may comprise a simple format image. Referring now to FIG. 2, pictured therein is an example architectural plan image 202. The architectural plan image 202 comprises markings outlining the positions of architectural components, including walls 208-1, windows 210-1, and doors 212-1. In the example image 202, markings also depict example fixtures 220-1 (e.g. toilets, sinks, etc.), dimensions 218-1, example furniture 216-1, crosshatching 214-1, and other administrative information 222-1. These additional features (214-1, 216-1, 218-1, 220-1 and 222-1) may not be of particular interest and may preferably be disregarded. Preferably, the systems and methods described herein may detect architectural components, such as windows, walls and doorways (208-1, 210-1, and 212-1 respectively) while disregarding additional features (e.g. 214-1, 216-1, 218-1, 220-1 and 222-1).

In some examples, distortion or artifacts (not pictured in example image 202) may be present within the architectural plan data. Such distortion or artifacts may originate from the application of lossy compression schemes to the architectural plan data. In some examples, architectural plan data may be generated by scanning hard copy architectural plans using an image scanner. In such examples, distortion or artifacts may be imparted into electronic architectural plan data, as hard copy architectural plans may comprise damage, dust or other debris that may be translated to the electronic architectural plan data during the scanning process. Preferably, the systems and methods described herein may detect architectural components, such as windows, walls and doorways, while disregarding distortion, degradation and artifacts.

In some examples, architectural plan data may comprise a scale (e.g. dimension 218-1 of FIG. 2), depicted therein. The scale may comprise a number of pixels, wherein the number of pixels corresponds to a real-world dimension (e.g. 1.70 m for dimension 218-1). For example, the architectural plan data may comprise a scale, disclosing that 20 pixels corresponds to 1.70 m of real-world length. Such information may be applied to determine the dimensions of components described within the architectural plan data.

The architectural plan data may comprise various resolutions, wherein resolution is defined by number of total image pixels in each dimension. The trained machine learning model may be resolution limited, in that it may be configured to process inputs of a certain maximum resolution. In such examples, the architectural plan data may be resized or compressed before input.

At step 104, a translated architectural plan is received as an output from the trained machine learning model.

The translated architectural plan may comprise data detailing the position of architectural components, in a simple format that may be readily machine translated to a vector format. For example, the output at step 104 may comprise a simple format image, comprising only a fixed number of total colors. Each color may correspond to a different class of feature. For example, the simple format image output may comprise two colors, wherein the first color is used to denote walls, while the second color is used to denote windows. Preferably, the colors chosen to depict different features are easily differentiable, such that they may be easily parsed and differentiated by machine automated methods.

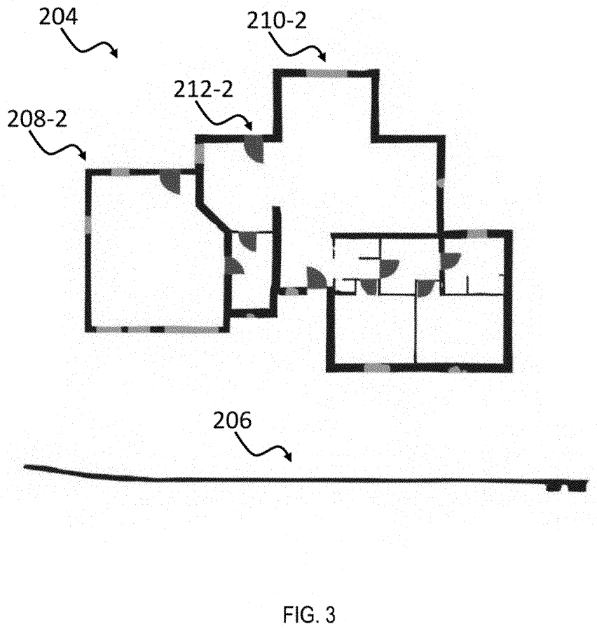

Referring now to FIG. 3, pictured therein is an example translated architectural plan 204. The translated architectural plan 204 is the output corresponding to the input of example architectural plan 202. The translated plan 204 comprises solid color areas depicting detected walls 208-2, windows 210-2 and doorways 212-2, pictured in blue, green and red respectively. The translated plan 204 has had all other extraneous data, such as example fixtures 220-1, dimensions 218-1, example furniture 216-1, crosshatching 214-1, and other administrative information 222-1 from the example architectural plan 202 stripped away.

As described previously, the machine learning model may output a simple format translated image, comprising features that may be readily vectorized through a contourization process. The output image may then be provided to another software module for contourization, wherein a raster or bitmap format image is converted to a discrete set of contours, which may be described parametrically in some examples. After contourization, a vector format architectural plan, detailing the positions of key architectural components, such as walls, windows and doorways may be outputted. The vector format output may advantageously be upscaled without a loss of quality or fidelity. Additionally, the vector format output may be more readily parsed by a machine, for purposes such as automated length, area and volume measurement, route planning, construction planning and generation of 3D models from the plan for visualization, simulation or training. Such models and plans may be applied in first response related use cases, wherein first responders may be provided with map data before responding to an incident, to better prepare for the first response.

While the example image 204 of FIG. 3 comprises three unique colors, each denoting an architectural feature class (walls 208-2, windows 210-2 and doorways 212-2 in blue, green, and red respectively), in other examples, more feature classes may be present. For example, the training set may be generated such as to differentiate between sliding doors and hinged doors, wherein each class of doors may be identified by a unique color.

In other examples, identifiers other than colors may be used to differentiate between features. For example, specific patterns, such as crosshatching may denote walls.

In other examples, only a single feature class may be of interest. For example, it may be determined that only walls are of interest. In such an example, a binary color system may be used. Walls may be denoted black areas, while the remainder of the image may remain white.

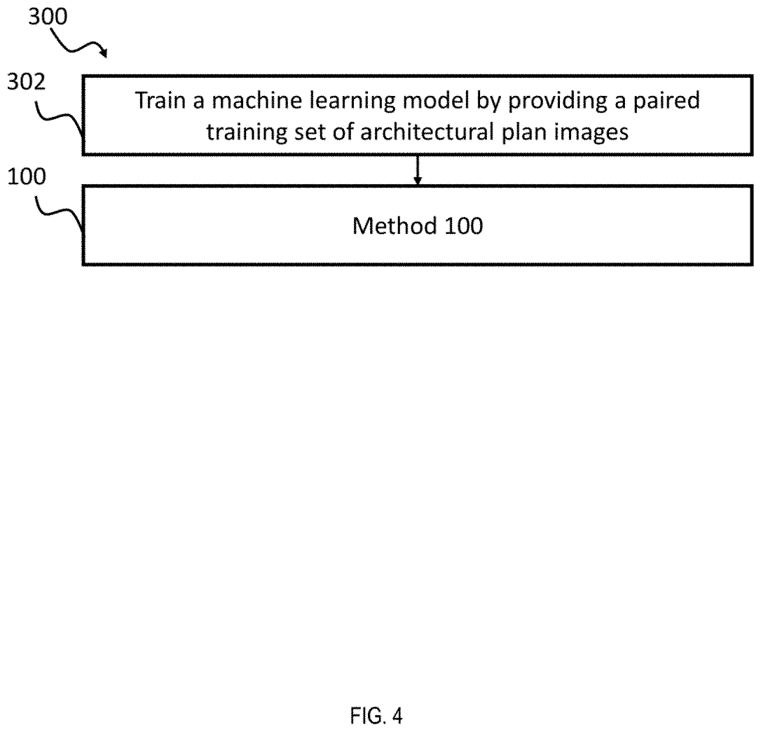

Referring now to FIG. 4, pictured therein is a method 300 of generating a translated architectural plan. Method 300 comprises steps 302, followed by any or all steps of method 100 as described above.

At step 302, a machine learning model is trained by providing a paired training set of architectural plan images.

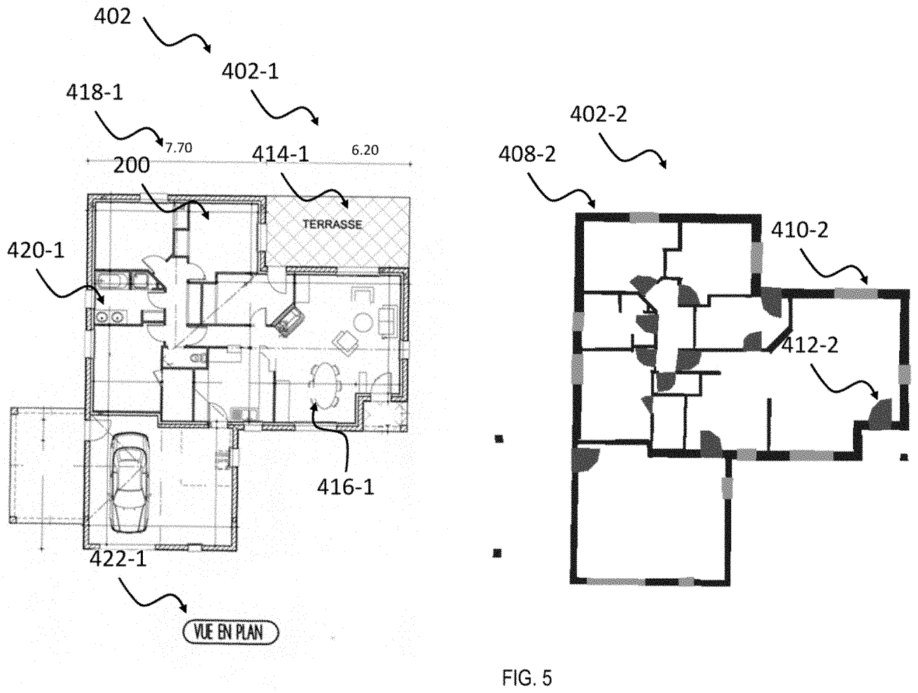

Referring now to FIG. 5, pictured therein is a single pair 402 of architectural plan training images, 402-1, 402-2. Each image of the pair 402 depicts the same building structure. Image 402-1 comprises a base architectural plan, in bitmap format. Image 402-1 comprises core architectural features, as well as example fixtures 420-1 (e.g. toilets, sinks, etc.), dimensions 418-1, example furniture 416-1, crosshatching 414-1, and other administrative information 422-1. Image 402-2 comprises the translated architectural plan, wherein core architectural features, such as walls 408-2, windows 410-2 and doorways 412-2 are depicted in specific single colors (blue, green and red respectively). Image 402-2 may be generated manually by a skilled operator, by tracing features presented in image 402-1, and applying the appropriate color mask to each feature.

While in the example of FIG. 5, three classes of features are present, each depicted in a unique color, comprising walls 208-2, windows 210-2 and doorways 212-2 in blue, green and red respectively, in other examples, more or less than three classes may be present.

Referring back to FIG. 4, at step 302, paired training data, such as that in the example of FIG. 5, may be provided to a machine learning model for training of the model. Once the model has been provided training data, and has been successfully trained, the model may be referred to as a trained model. When the trained model is provided an input, the model will generate an output according to the data comprising the training set. In some examples, the machine learning model may comprise at least one neural network. In some examples, the machine learning model may comprise a generative adversarial network based model.

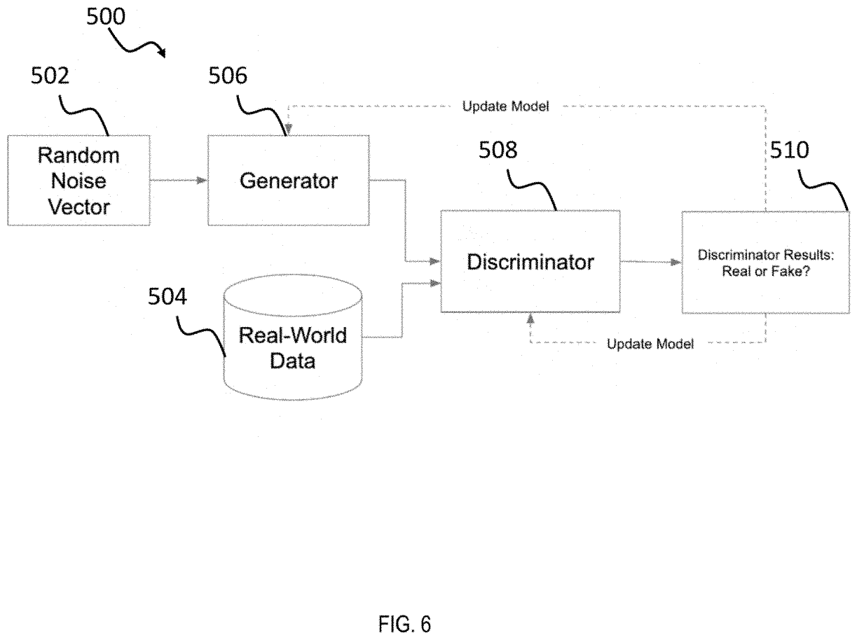

Referring now to FIG. 6, pictured therein is a block diagram of a generalized generative adversarial network (GAN) neural network 500. The generative adversarial network comprises a random noise vector 502, real world data input 504, generator 506, discriminator 508, and discriminator result 510, wherein generator 506 and discriminator 508 each comprise neural networks. Real world data 504 is inputted into the network 500. The generator 506 and discriminator 508 are trained using the real-world data 504. The network 500 may additionally comprise hyperparameters (not pictured), which may be tuned manually until the network 500 produces a result aligning with an operator's desire.

After training, the generator 506 is configured to generate a sample upon command, or input of a random noise vector 502, and the discriminator 508 is configured to be provided with the sample. The discriminator 508 may comprise binary classification network, which is configured to output a binary determination (at 510) as to whether the provided sample is a real sample, as per provided real-world data, or a generated/incorrect sample, according to the real-world data 504. The discriminator 508 result 510, as well as accompanying data, may be fed back to both the generator 506 and discriminator 508, such that the generator 506 may update parameters of its model, and iterate the generated sample. The model 500 may be run continuously, until the discriminator 508 outputs a determination at 510, that the generated sample is “real”, wherein the discriminator 508 is unable to discriminate between a real-world data 504 sample and the generated sample. At such a point, the sample is determined to be the final output of the model 500.

In the example of methods 100 and 300, a GAN such as network 500 described above in reference to FIG. 6 may be employed as the trained machine learning model. In some examples, a variation of a GAN, such as network 500 may be employed in methods 100 and 300. For example, a GAN purposely design for image style shifting or image to image translation may be applied. Such GANs are configured to convert an image from one style domain to another style domain, according to the provided paired training dataset.

In some examples, pix2pixHD or a similar model or software package may be employed by methods 100 and 300 as the image translation machine learning model. Pix2pixHD comprises a GAN based machine learning model, which may synthesize high resolution images (e.g. up to 2048×1024 pixels), and may provide for image style translation functionality when provided with an appropriate paired image training set. The pix2pixHD generator component comprises groups of convolution layers, followed by groups of residual network layers followed by groups of deconvolution layers. The pix2pixHD discriminator component comprises a multiscale discriminator, wherein multiple discriminators are employed, each evaluating inputs at different scales, such that various receptive fields and levels of detail may be evaluated by the discriminator.

In some examples, wherein pix2pixHD is employed, hyperparameters may include number of iterations, number of decay iterations, learning rate, loadSize, fineSize, Adam Optimizer Momentum, BatchSize, and n_layers_D. In some examples, pix2pixHD hyperparameters may be configured such that number of iterations=200, number of decay iterations=200, learning rate=0.0002, loadSize=1024, fineSize, =512 Adam Optimizer Momentum=0.5, BatchSize=1, and n_layers_D=3. Such a configuration may result in good performance, and high-quality output. In other examples, hyperparameters may vary from the hyperparameters provided herein.

In examples wherein pix2pixHD, or a similar method is applied, paired training images, such as 402-1 and 402-2 of FIG. 5, may be provided to the GAN as real world data 504 at the training phase to train the model.

After training the model, instead of inputting random noise vector 502 into generator 506, an image (e.g. 202) may be inputted. The generator 506 may then generate an output corresponding to the inputted image. For example, an architectural plan image, such as image 202 may be provided as an input to the generator 506. The generator 506 may generate a corresponding output, and provide the output to the discriminator 508. The network 500 may iterate until the discriminator 508 is unable to differentiate between training images and generated images provided by the generator 506.

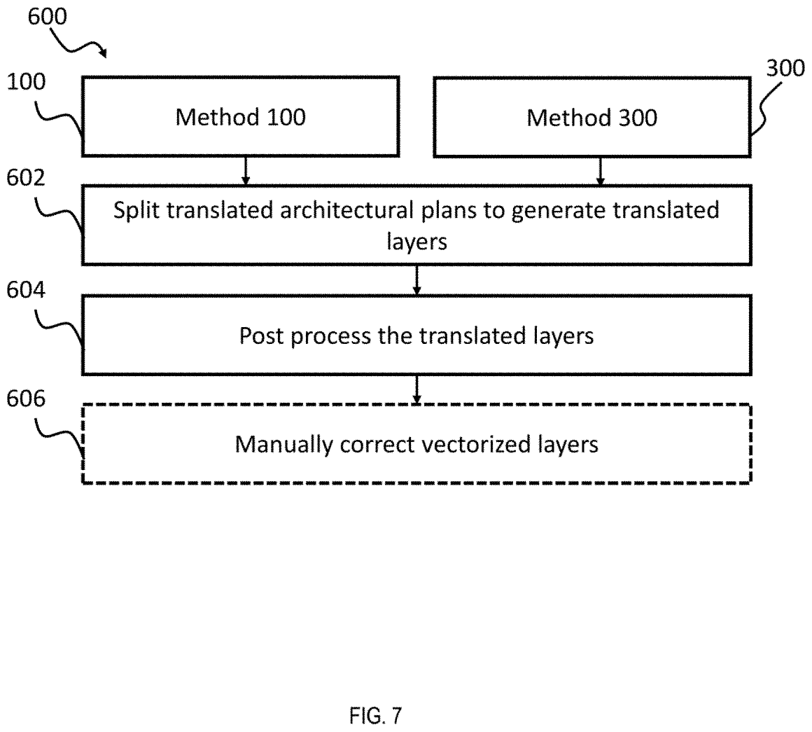

Referring now to FIG. 7, pictured therein is a method 600 of generating a vectorized architectural plan. Method 600 may comprise any or all steps of methods 100 or 300. Method 600 comprises steps 602, 604 and optionally, 606.

At step 602, the translated architectural plans are split into layers, generating translated layers. Each layer may comprise a unique class of architectural features or set of classes or architectural features. As the translated architectural plans may comprise multiple classes of features, each depicted by a unique color, layers may be readily separated by machine methods. For example, color thresholding may be applied by a machine method.

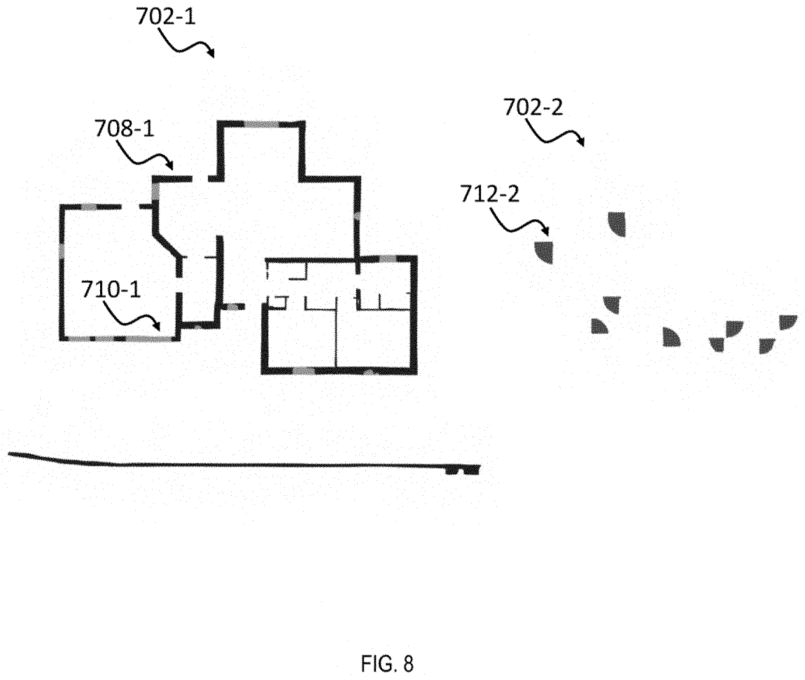

Referring now to FIG. 8, pictured therein is an example set of images, 702-1, and 702-2, depicting a translated architectural plan, split into translated layers, wherein each translated layer comprises a subset of the architectural features present in the translated architectural plan. The translated architectural plan 402-1 comprises blue components corresponding to walls 408-2, green components corresponding to windows 410-2, and red components corresponding to doorways 412-2. The translated layer split image 702-1 comprises only windows 710-1 depicted in green, and walls 708-1 depicted in blue. The translated layer split image 702-2 comprises only doorways 712-2 depicted in red.

Referring back to FIG. 7, at step 604, each translated layer is post-processed to produce processed translated layers. Post-processing steps may comprise simplification, contourization, and room segmentation.

During a contourization process, single color raster image features are converted to vector image features, generating a vectorized architectural plan. The contourization process employed may be particularly configured for the contourization of images comprising architectural plan features. For example, the contourization process may be configured such that is it known that features such as walls (e.g. depicted in a single shade of blue) may comprise approximately rectangular forms. The contourization process may be performed on the translated architectural plan, the translated layers, or processed translated layers. In some examples, wherein contourization is performed on translated layers, the contourized output of each split layer may be combined back into a comprehensive file, comprising all layers, in vector format output.

In some examples, the scikit-image measure module may be employed for contourization. In some examples, the find_contours function of the scikit-image measure module may be employed for contourization. The find_contours function may apply the marching squares method to compute contours for a given image array.

During a simplification process, identified areas corresponding to walls, doors or windows may be analyzed for irregularities. It may be known that walls in general may comprise certain regular shapes, for examples, rectangles. If wall sections are identified comprising usual shape characteristics, such sections may be identified as irregular, and automatically removed, or flagged for review by a human operator.

In other examples, detected areas with irregular shapes may be simplified by skewing the area such that it aligns with a regular shape. For example, detected areas which comprise nearly rectangular forms may be skewed such that their boundaries resemble neat rectangular forms.

In other examples, a Douglas-Peucker algorithm-based method may be applied to vectorized translated layers for vertex simplification. In other examples, other vertex simplification processes may be applied.

In other examples, other software modules may be applied for contourization. In some examples, the marching squares method may be applied.

In some examples, contourization may be performed without first splitting the translated architectural plan into translated layers. For example, an alternate method may be employed, analogous to method 600, but omitting step 602, and only comprising contourization as post-processing at step 604. In some examples, the vectorized architectural plan may be split into vectorized layers.

During a room segmentation process, a segmentation software module may be provided with a layer split, translated architectural plan. The segmentation software module may detect the boundaries of rooms, and output a series of room segmented outputs, wherein each output comprises a single room. In other examples, the segmentation software module may output a room map, comprising information which may be referenced to determine which portions of the split, translated architectural plan comprise separate rooms. In some examples, the segmentation software module may comprise a machine learning model, such as a trained neural network.

In some examples, the segmentation process may be performed on a vectorized architectural plan.

In some examples, room segmentation may comprise the following steps: receive a vector representation of the walls and doors, inflate the door polygons, for each door: locate the intersection with wall geometries, compute the convex hull of the intersection points, convert the convex hull to a series of linestrings, compute the difference between the wall geometries and the linestrings, and select the second longest linestring as the “door entrance” to segment the walkable polygons into rooms. The second longest linestring may be chosen, as doorways may be depicted in translated architectural plans using an irregular shape showing the swing area of the door. After the completion of these steps, the rooms may be segmented.

In some examples, room segmentation may comprise the following steps: receive a vector representation of walkable space and door geometries, inflate the walkable and door geometries, for each door: subtract the door from the walkable polygons, locate the intersection between the door geometry and adjacent walkable geometries, and merge the door into the walkable geometry that it shares the most area with. After the completion of these steps, the rooms may be segmented.

In some examples, a scaling operation may be performed at step 604. For example, scale data present within the original architectural plan may be applied to the translated or vectorized architectural plan, such that the lengths of translated or vectorized features within the translated or vectorized architectural plan are associated with real world dimensions.

In some examples of method 600, only a subset of the post processing operations described herein may be performed at step 604.

At step 606, subcomponents (e.g. vectorized layers) may be manually corrected by an operator. Depending on the size, variety and quality of the training set of which the machine learning model has been trained, the translated architectural plan may comprise slight irregularities or errors. A skilled operator may quickly detect such errors and perform corrections. For example, the operator may remove extraneous areas. For example, referring now to FIG. 3, pictured therein is a translated architectural plan 204. Feature 206 is extraneous architectural data, which has been incorrectly labelled by the machine learning model as a wall. An operator may manually remove this feature to correct this error at step 606.

In some examples, manual correction processes may be conducted using any vector or raster image editing software, or other proprietary tools, where appropriate.

In some examples, manual correction processes may be employed at other points of method 600. For example, manual correction may be performed before contourization.

In some examples of method 600, manual correction processes may be prompted by another process. For example, during post processing at step 604, a simplification process may detect irregularities in the vectorized architectural plan, and may prompt an operator to perform a manual correction process.

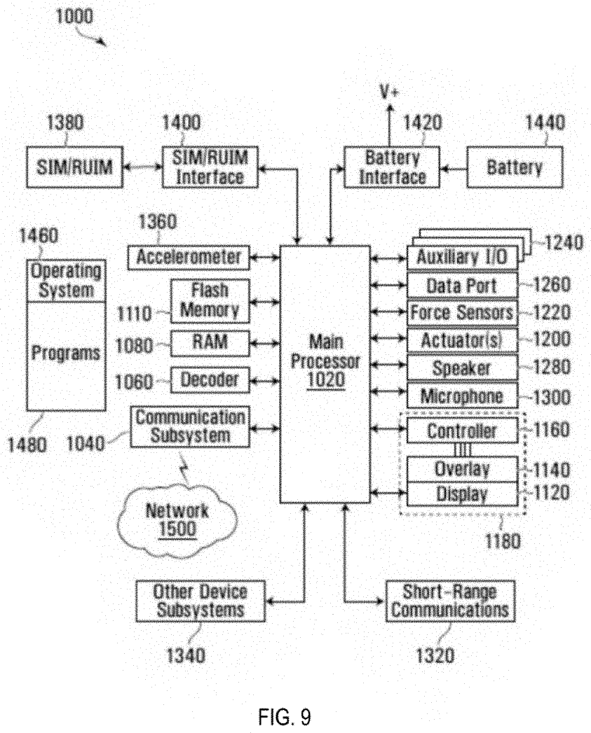

Referring now to FIG. 9, FIG. 9 shows a simplified block diagram of components of a device 1000, such as a mobile device or portable electronic device. Device 1000 may be utilized for generating a vectorized architectural plan as described above in reference to FIGS. 1 to 8. The device 1000 includes multiple components such as a processor 1020 that controls the operations of the device 1000. Communication functions, including data communications, voice communications, or both may be performed through a communication subsystem 1040. Data received by the device 1000 may be decompressed and decrypted by a decoder 1060. The communication subsystem 1040 may receive messages from and send messages to a wireless network 1500.

The wireless network 1500 may be any type of wireless network, including, but not limited to, data-centric wireless networks, voice-centric wireless networks, and dual-mode networks that support both voice and data communications.

The device 1000 may be a battery-powered device and as shown includes a battery interface 1420 for receiving one or more rechargeable batteries 1440.

The processor 1020 also interacts with additional subsystems such as a Random Access Memory (RAM) 1080, a flash memory 1100, a display 1120 (e.g. with a touch-sensitive overlay 1140 connected to an electronic controller 1160 that together comprise a touch-sensitive display 1180), an actuator assembly 1200, one or more optional force sensors 1220, an auxiliary input/output (I/O) subsystem 1240, a data port 1260, a speaker 1280, a microphone 1300, short-range communications systems 1320 and other device subsystems 1340.

In some embodiments, user-interaction with the graphical user interface may be performed through the touch-sensitive overlay 1140. The processor 1020 may interact with the touch-sensitive overlay 1140 via the electronic controller 1160. Information, such as text, characters, symbols, images, icons, and other items that may be displayed or rendered on a portable electronic device generated by the processor 102 may be displayed on the touch-sensitive display 118.

The processor 1020 may also interact with an accelerometer 1360 as shown in FIG. 2. The accelerometer 1360 may be utilized for detecting direction of gravitational forces or gravity-induced reaction forces.

To identify a subscriber for network access according to the present embodiment, the device 1000 may use a Subscriber Identity Module or a Removable User Identity Module (SIM/RUIM) card 1380 inserted into a SIM/RUIM interface 1400 for communication with a network (such as the wireless network 1500). Alternatively, user identification information may be programmed into the flash memory 1100 or performed using other techniques.

The device 1000 also includes an operating system 1460 and software components 1480 that are executed by the processor 1020 and which may be stored in a persistent data storage device such as the flash memory 1100. Additional applications may be loaded onto the device 1000 through the wireless network 1500, the auxiliary I/O subsystem 1240, the data port 1260, the short-range communications subsystem 1320, or any other suitable device subsystem 1340.

For example, in use, a received signal such as a text message, an e-mail message, web page download, or other data may be processed by the communication subsystem 1040 and input to the processor 1020. The processor 1020 then processes the received signal for output to the display 1120 or alternatively to the auxiliary I/O subsystem 1240. A subscriber may also compose data items, such as e-mail messages, for example, which may be transmitted over the wireless network 1500 through the communication subsystem 1040.

For voice communications, the overall operation of the portable electronic device 1000 may be similar. The speaker 1280 may output audible information converted from electrical signals, and the microphone 1300 may convert audible information into electrical signals for processing.

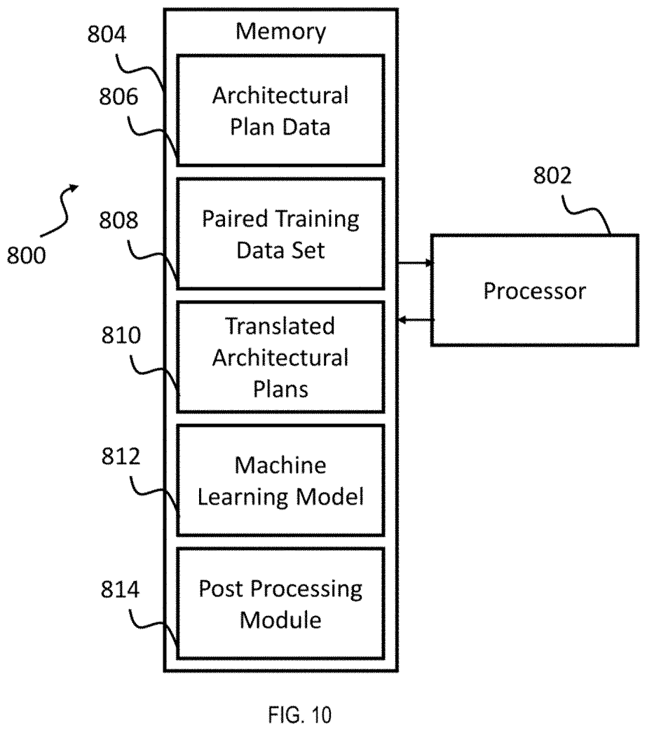

Referring now to FIG. 10, pictured therein is a block diagram of a system 800 for generating a translated or vectorized architectural plan. System 800 comprises memory 804 and processor 802. Memory 804 and processor 802 are configured such that they may readily communicate with and pass data to one another. Any one or all of the subcomponents of system 800 may comprise a mobile device or portable electronic device, or subcomponents thereof, as described above in reference to device 1000.

Processor 802 may be any processor known in the art for executing machine instructions.

Memory 804 may be any form of memory known in the art that may store machine instruction data, and input/output data, such as training set data, input architectural plan data, and output translated architectural plan data.

Memory 804 may further comprise architectural plan data 806, paired training data set 808, translated architectural plans 810, machine learning model 812 and post processing module 814.

Architectural plan data 806 may comprise bitmap format architectural plan images, as demonstrated by plan image 202 of FIG. 2.

Paired training data set 808 may comprise a paired set of architectural plans and translated architectural plans, as demonstrated by 402 of FIG. 5.

Translated architectural plans 810 may comprise the output of machine learning model 812. For example, translated architectural plans 810 may resemble translated architectural plan 204 of FIG. 3.

Machine learning model 812 may comprise a machine learning model configured to accept a bitmap format architectural plan as an input, and output a translated architectural plan. In some examples, machine learning model 812 may comprise a generative adversarial network, like the network 500 of FIG. 6. In some examples, the generative adversarial network may comprise pix2pixHD.

Post processing module 814 may comprise a software module which may perform post processing operations as described above in reference to step 604 of method 600.

System 800 may be configured to conduct methods 100, 300 or 600, as described herein. In some examples, system 800 may comprise additional components.

While the above description provides examples of one or more apparatus, methods, or systems, it will be appreciated that other apparatus, methods, or systems may be within the scope of the claims as interpreted by one of skill in the art.

What is claimed is the systems and methods as generically and specifically described herein:

1. A method of generating translated architectural plans, the method comprising:
inputting an architectural plan into a trained machine learning model; and
receiving a translated architectural plan as an output from the trained machine learning model.

2. The method of claim 1, wherein the trained machine learning model comprises a generative adversarial network.

3. The method of claim 1, wherein the trained machine learning model is trained by providing a paired training set of architectural plan images.

4. The method of claim 1, wherein the paired training set comprises corresponding architectural plan and translated architectural plan pairs.

5. The method of claim 1, wherein the translated architectural plan comprises at least two classes of architectural features, the method further comprising:
splitting the translated architectural plan to generate translated layers; and
post processing the translated layers to produce processed translated layers.

6. The method of claim 5, wherein post processing comprises contourization, generating a vectorized architectural plan.

7. The method of claim 5, wherein post processing comprises room segmentation.

8. The method of claim 5, wherein the translated layers comprise at least one of walls, windows or doors.

9. The method of claim 5, further comprising manually correcting the translated layers.

10. The method of claim 1, the method further comprising:
performing contourization on the translated architectural plan, generating a vectorized architectural plan.

11. The method of claim 10, further comprising splitting the vectorized architectural plan into vectorized layers.

12. The method of claim 11, wherein the vectorized layers comprise at least one of walls, windows or doors.

13. A computer system for generating translated architectural plans, the system comprising: at least one processor and a memory having stored thereon instructions that, upon execution, cause the system to perform functions comprising:
inputting an architectural plan into a trained machine learning model; and
receiving a translated architectural plan as an output from the trained machine learning model.

14. The system of claim 13, wherein the trained machine learning model comprises a generative adversarial network.

15. The system of claim 13, wherein the trained machine learning model is trained by providing a paired training set of architectural plan images.

16. The system of claim 13, wherein the paired training set comprises corresponding architectural plan and translated architectural plan pairs.

17. The system of claim 13, wherein the translated architectural plan comprises at least two classes of architectural features, the system further comprising:
splitting the translated architectural plan to generate translated layers; and
post processing the translated layers to produce processed translated layers.

18. The system of claim 17, wherein post processing comprises contourization, generating a vectorized architectural plan.

19. The system of claim 17, wherein the translated layers comprise at least one of walls, windows or doors.

20. The system of claim 17, further comprising manually correcting the translated layers.
